(19) United States
(12) Patent Application Publication
(10) Pub. No.: US 2010/0072976 A1
(43) Pub. Date: Mar. 25, 2010

(54) SENSING ELEMENT, MANUFACTURING METHOD THEREOF, AND BIOLOGICAL DETECTION SYSTEM EMPLOYING SUCH SENSING ELEMENT

(75) Inventors: Jeng-Tzong Sheu, Hsinchu City (TW); Chen-Chia Chen, Changhua County (TW); Yaw-Kuen Li, Hsinchu City (TW); Ko-Shing Chang, Tainan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: NATIONAL CHIAO TUNG UNIVERSITY, Hsinchu City (TW)

(21) Appl. No.: 12/497,186

(22) Filed: Jul. 2, 2009

(30) Foreign Application Priority Data
Sep. 23, 2008 (TW) 097136557

(51) Int. Cl. G01N 27/00; H01L 29/786; H01L 21/28

(52) U.S. Cl. 324/71.1; 257/253; 257/57; 257/66; 438/49; 257/E29.273; 257/E29.289; 257/E29.292; 257/E21.19

(57) ABSTRACT

A sensing element includes a field-effect transistor (FET) with an ultra-thin channel, a reference electrode, a first and a second passivation layer, and a microchannel. The first and the second passivation layer enclose a first and a second portion of the FET, respectively. The microchannel is bonded to the first and the second passivation layer, such that the microchannel is extended across the channel of the ultra-thin channel FET. The ultra-thin channel has a chemically or physically modified surface. When an analyte to be tested passes through the microchannel and is in contact with the modified surface of the ultra-thin channel, it results in changes in the conductance of the ultra-thin channel FET. Trace detection may be conducted on the analyte by observing changes in the conductance. A method for manufacturing the sensing element and a biological detection system employing the sensing element are also provided.

### FIELD OF THE INVENTION

The present invention relates to a sensing element, and more particularly to a sensing element that includes a transistor with a surface-modified ultra-thin channel and a microchannel. The present invention also relates to a method of manufacturing the sensing element and a biological detection system employing the sensing element.

### BACKGROUND OF THE INVENTION

A field-effect transistor (FET) is a semiconductor device that utilizes electric field effect to control the current. Due to its advantages of small size, light weight, low power consumption, long lifetime, high input impedance, low noise, good thermal stability, enhanced anti-radiation ability, and simple manufacturing procedures, the FET has a variety of applications, and has particularly been widely used in large-scale integrated circuit (LSI) and very-large-scale integrated circuit (VLSI).

Moreover, since a nano-scale FET has extremely high electric sensitivity, it has also been used as a basic framework of biological sensors to be applied in the biological detection field. However, such FET comprises a channel made of carbon nanotubes, and it is therefore difficult to align nanotubes to makes the device, separate metal from the co-existing carbon tubes that have semiconductor properties, modify the surfaces of the nano carbon tubes, and scale to large area manufacture. As to silicon-nanowire FETs, while manufacturing with a top-down process, expensive manufacturing equipments are required and thus leads to undesirable increase of the manufacturing cost. On the other hand, while the silicon-nanowire FET is manufactured with a bottom-up process, different problems, such as difficult to fabricate the silicon nanowires as devices, control of the radius uniformity of silicon nanowires, and low yield in large-area process, etc., will be encountered.

A sensing element, a manufacturing method thereof, and a biological detection system employing such sensing element for use in the detection of biological or chemical species are therefore proposed in this invention. The thickness of an FET forming the sensing element may be reduced to nano scale through a conventional semiconductor manufacturing process, so that the sensing element may possess superior electrical sensitivity in application to the detection of biological and chemical species.

### SUMMARY OF THE INVENTION

A primary object of the present invention is to provide a sensing element, a manufacturing method thereof, and a biological detection system employing such sensing element, so as to solve the problems of difficult manufacturing process and high manufacturing cost as found in conventional sensing elements.

Another object of the present invention is to provide a sensing element, a manufacturing method thereof, and a biological detection system employing such sensing element, so as to increase the sensitivity of the sensing element.

To achieve the above and other objects, the sensing element according to the present invention includes a field-effect transistor (FET), a reference electrode, a first passivation layer, a second passivation layer, and a microchannel. The FET has an ultra-thin channel, the first passivation layer encloses a first portion of the FET, the second passivation layer encloses a second portion of the FET, and the microchannel is bonded to the first and the second passivation layer to extend across the channel of the ultra-thin channel FET. The ultra-thin channel has a modified surface. The FET correspondingly generates an electric signal when an analyte to be tested passes through the microchannel to get inteact chemically or physically with the modified surface of the ultra-thin channel.

Preferably, the analyte to be tested is a biological material, such as the ribonucleic acid (RNA), deoxyribonucleic acid (DNA), enzymes, proteins, viruses or lipids, or a chemical substance.

The method of manufacturing the aforementioned sensing element according to the present invention includes the following steps:

(a) providing an FET having an ultra-thin channel, and the ultra-thin channel having a thickness smaller than 50 nm;

(b) defining a reference electrode, a source electrode, and a drain electrode;

(c) depositing a passivation layer;

(d) heat bonding a microchannel to the passivation layer; and

(e) modifying a surface of the ultra-thin channel to complete the sensing element.

The surface of the ultra-thin channel may be chemically or physically modified. In the case of chemical surface modification, chemicals used for this purpose may be silane coupling agents with amino group, carboxyl group, aldehyde group, or thiol group; or metallic complexes with nickel, iron, gold, silver, or platinum. Alternatively, in the case of physical surface modification, it may be achieved through non-covalent bonding.

To achieve the above and other objects, the biological detection system for detecting a biological material according to the present invention includes a sensing element of the present invention and a signal output device. The sensing element may detect an electric signal, and the signal output device outputs and records the electric signal. High-sensitive detection may be implemented on the biological material by observing changes in the electric signal.

Preferably, the signal output device is a semiconductor parameter analyzer.

Preferably, the electric signal is a current signal, a voltage signal, or a conductance signal.

With the above arrangements, the sensing element, the manufacturing method thereof, and the biological detection system employing the sensing element according to the present invention provide at least one or more of the following advantages:
(1) The channel thickness of the sensing element may be reduced by repeated oxidation and wet etching, and may be highly accurately controlled through chemical vapor deposition (CVD), so that the problem of high manufacturing cost in the conventional sensing element may be solved.
(2) The thickness of the FET of the sensing element may be reduced to a nano scale through conventional semiconductor manufacturing process, so that the FET may possess superior electrical sensitivity in application of high-sensitive detection of biological and chemical species.
(3) The sensing element has a Debye length much larger than the thickness of the ultra-thin channel, and therefore has sensitivity superior to that of prior art sensors.

### BRIEF DESCRIPTION OF THE DRAWINGS

The structure and the technical means adopted by the present invention to achieve the above and other objects may be best understood by referring to the following detailed description of the preferred embodiments and the accompanying drawings, wherein

FIG. 1A is a side view of a sensing element according to the present invention;

FIG. 1B is an exploded perspective view of the sensing element of FIG. 1A;

FIG. 2A is a conceptual view showing a first example of forming the sensing element of the present invention;

FIG. 2B is a conceptual view showing a second example of forming the sensing element of the present invention;

FIG. 3 is a flowchart showing the steps included in a method of manufacturing the sensing element of the present invention;

FIG. 4 illustrates the manufacture of the sensing element of the present invention;

FIG. 5 shows electric properties of the sensing element of the present invention obtained at different modified channel surfaces;

FIG. 6 is a block diagram of a biological detection system according to the present invention, in which an ultra-thin channel FET is employed;

FIG. 7 shows electrical responses of the biological detection system of the present invention in performing biological detection; and

FIG. 8 shows results from tests conducted on buffer solutions with different pH values using the sensing element of the present invention.

### DETAILED DESCRIPTION OF THE PREFERRED EMBODIMENTS

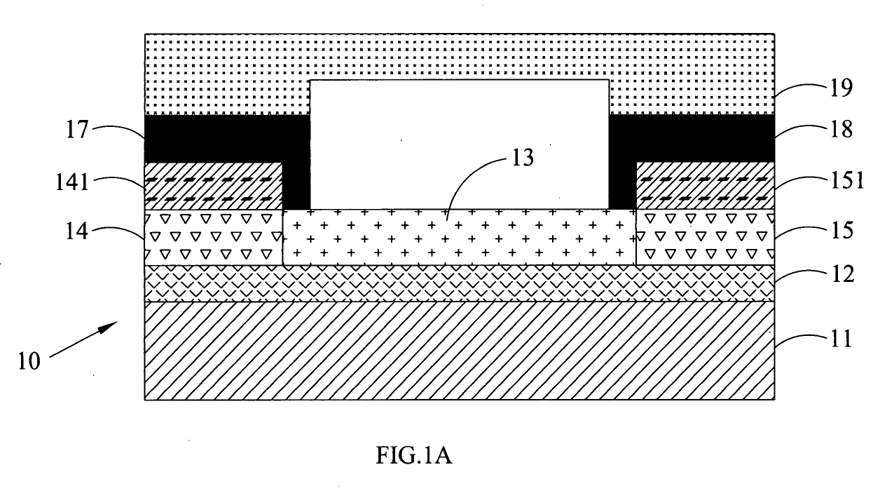

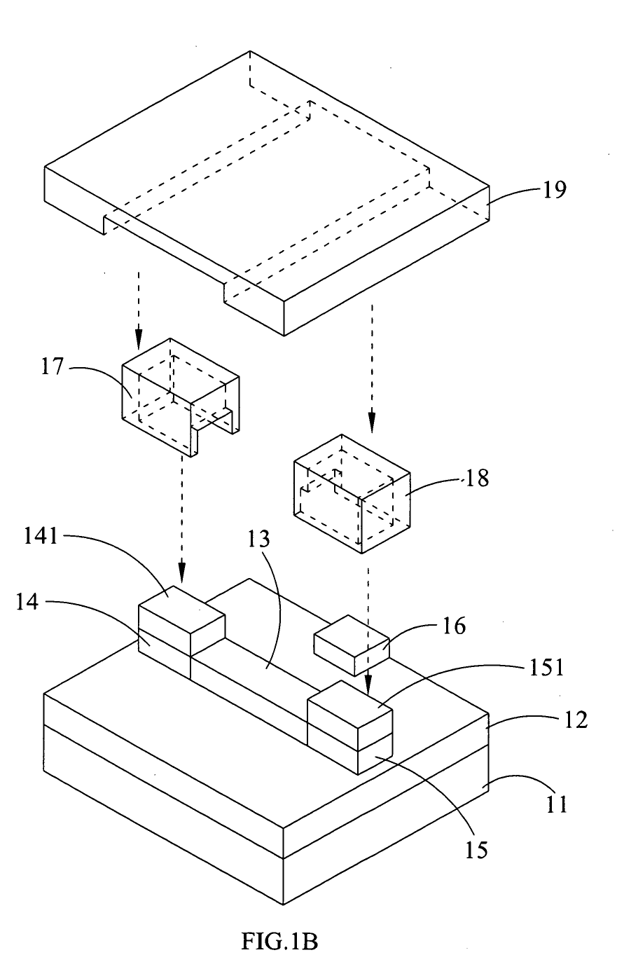

Please refer to FIGS. 1A and 1B that are side view and exploded perspective view, respectively, of a sensing element according to an embodiment of the present invention. As shown, the sensing element includes a field-effect transistor (FET) 10, a reference electrode 16, a source electrode 141, a drain electrode 151, a first passivation layer 17, a second passivation layer 18, and a microchannel 19.

The FET 10 includes a substrate 11, an insulating layer 12, an active layer 13, a source 14, and a drain 15. The insulating layer 12 is deposited atop the substrate 11. The substrate 11 is preferably made of a monocrystalline silicon material or a glass material, and the insulating layer 12 is preferably made of a silicon compound, such as silica (SiO₂) or silicon nitride (Si₃N₄).

The active layer 13 includes an ultra-thin channel, and is deposited atop the insulating layer 12. The source 14 is an electrically conductive body and is in electric contact with the active layer 13. The drain 15 is another electrically conductive body and is also in electric contact with the active layer 13. The drain electrode 141 and the drain electrode 151 are deposited atop the source 14 and the drain 15, respectively. The active layer 13 is preferably made of a monocrystalline silicon material, a polycrystalline silicon material, or an amorphous silicon material, and preferably has a thickness smaller than 50 nm.

The ultra-thin channel of the FET 10 is chemically or physically surface-modified. In the case of chemical surface modification, chemicals used for this purpose may be silane coupling agents with amino group, carboxyl group, aldehyde group, or thiol group; or metallic complexes with nickel, iron, gold, silver, or platinum. Alternatively, in the case of physical surface modification, it may be achieved through non-covalent bonding.

The first passivation layer 17 is used to enclose the source electrode 141 of the FET 10, and the second passivation layer 18 is used to enclose the drain electrode 151 of the FET 10. The microchannel 19 is bonded to the first passivation layer 17 and the second passivation layer 18. The reference electrode 16 is provided on the FET 10. The first and the second passivation layer 17, 18 are preferably made of an insulating material, such as silica (SiO₂), silicon nitride (Si₃N₄), or aluminum oxide (Al₂O₃). The reference electrode 16 is preferably a gold, a platinum, or a silver chloride/chloride (AgCl/Cl) reference electrode. And, the microchannel 19 is preferably made of silicon, SiO₂, or other organic materials, such as polydimethylsiloxane (PDMS), polymeric material SU-8, polymethylmethacrylate (PMMA), or cyclic olefin copolymers (COC).

When an analyte is to be tested, which may be a biological material, such as the ribonucleic acid (RNA), deoxyribonucleic acid (DNA), enzymes, proteins, viruses or lipids, or a chemical substance, the analyte firstly passes through the microchannel 19 to be contact with the modified surface of the ultra-thin channel by bonding or adsorbing, the FET 10 would correspondingly generate an electric signal, such as a current signal, a voltage signal, or a conductance signal. Since the sensing element of the present invention has a Debye length larger than a thickness of the ultra-thin channel, the sensing element may have a sensitivity superior to other sensors of prior art. And, a user may select a proper substance for use in the surface modification according to the properties of the analyte to be tested.

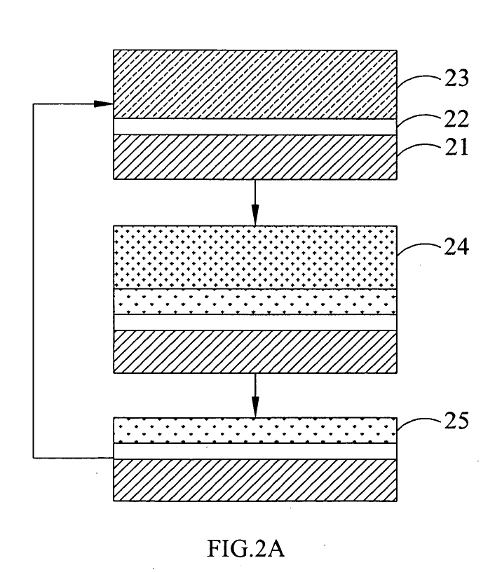

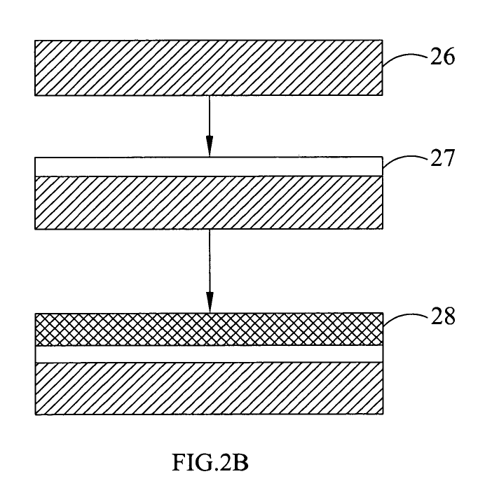

Please refer to FIG. 2A, which is a conceptual view showing a first example of forming the ultra-thin channel for the sensing element of the present invention. As shown, in this first example, an insulating layer 22 is formed atop a silicon substrate 21, and a monocrystalline silicone layer 23 is formed atop the insulating layer 22. After the monocrystalline silicone layer 23 is cleaned, the whole structure is positioned in an oxidation furnace, so as to grow a silica layer 24 in an oxygen-rich environment. Then, the silica layer 24 is etched using hydrofluoric acid. Thereafter, the formed structure is cleaned by using deionized water. When the above steps are repeatedly performed, an ideal ultra-thin channel 25 may be obtained.

Please further refer to FIG. 2B, which is a conceptual view showing a second example of forming the ultra-thin channel for the sensing element of the present invention. As shown, in this second example, a silicon substrate 26 is cleaned and then positioned in an oxidation furnace, so that a silica layer 27 is grown in an oxygen-rich environment. Then, allow a polycrystalline silicon film or an amorphous silicon film 28 to grow within a low-pressure chemical vapor deposition system. And, the polycrystalline or amorphous silicon film 28 is an ideal ultra-thin channel for the present invention.

From the above description, it is understood that the thickness of the channel for the sensing element of the present invention may be reduced through repeated oxidation and wet etching, and the channel thickness may be highly accurately controlled through chemical vapor deposition to thereby achieve the purpose of reducing the manufacturing cost of the sensing element.

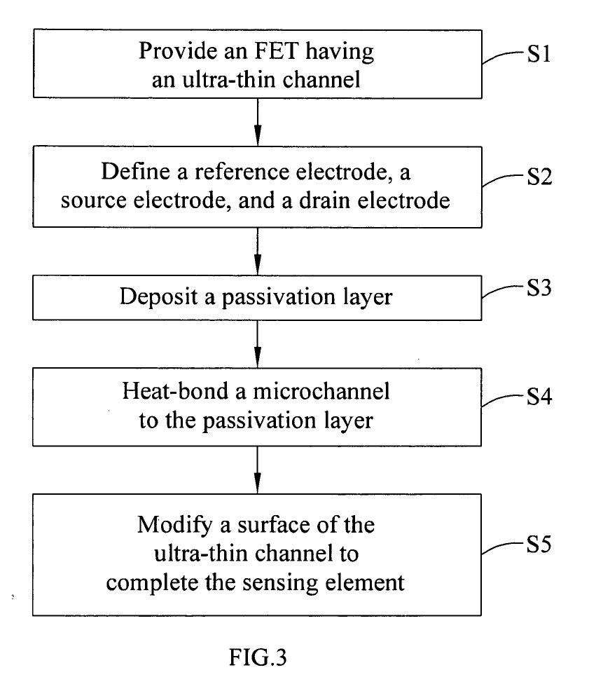

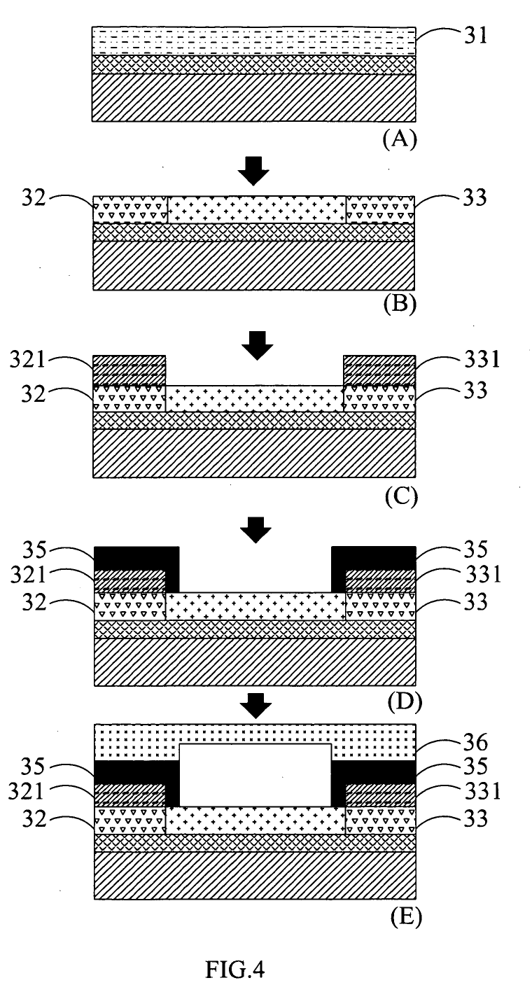

Please refer to FIG. 3, which is a flowchart showing the steps included in a method of manufacturing the sensing element of the present invention, and to FIG. 4 that illustrates the manufacture of the sensing element of the present invention. As shown, the method of manufacturing the sensing element of the present invention includes the following steps:

Step S1, in which an FET with an ultra-thin channel is provided. To do so, boron ions are implanted into an active layer 31 of an ultra-thin channel chip; then the chip is activated in a furnace at approximately 950° C. for about 30 minutes. Thereafter, lithography technique is employed to define a source 32 and a drain 33 on the chip; and heavy doping is performed by ion implantation. The chip is then activated in a rapid thermal annealing furnace at approximately 1050° C. for about 30 seconds. Finally, a sub-micro channel pattern is defined on the chip by etching to thereby obtain an ultra-thin channel FET, as shown by the illustrations (A) and (B) of FIG. 4. The ultra-thin channel so formed has a thickness smaller than 50 nm;

Step S2, in which a source electrode 321 and a drain electrode 331 are defined using lithography technique, as shown by the illustration (C) of FIG. 4;

Step S3, in which a passivation layer 35 is deposited to protect the source electrode 321 and the drain electrode 331, as shown by the illustration (D) of FIG. 4;

Step S4, in which a microchannel chip 36 is connected to the passivation layer 35 by heat bonding. To do so, first use ultraviolet-ozone plasma treatment to clean the microchannel chip 36 and the passivation layer 35, and then bond the microchannel chip 36 to the passivation layer 35. The structure is then heated on a hotplate at 80˜100° C. for about 4 hours; and,

Step S5, in which the surface of the ultra-thin channel is chemically or physically modified to complete the preparation of the sensing element, as the illustration (E) of FIG. 4. Since the surface modification has been described in previous paragraphs, it is not repeated herein.

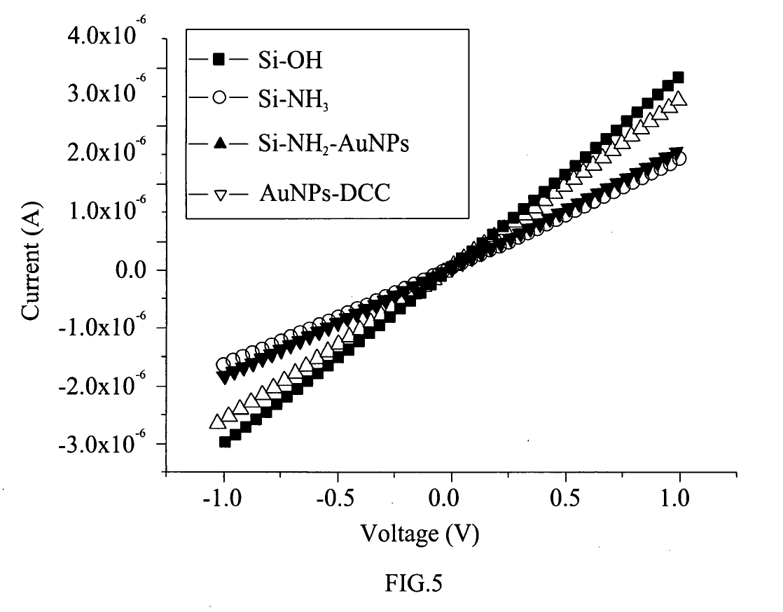

FIG. 5 shows the electrical properties of the sensing element of the present invention when the channel surface thereof has been modified in different manners. As shown, the Si—NH₃ curve is a current-voltage characteristic curve of the sensing element when the sensing element is chemically surface-modified using a silane coupling agent with amino group by positioning the sensing element in 0.01M˜0.1M N-(2-aminoethyl)-3-amino-propyl-trimethoxysilane (AEAPTMS) solution for 10 to 24 hours. The Si—NH₂—AuNPs curve is a current-voltage characteristic curve of the sensing element when the sensing element having been chemically modified with amino-group is further chemically modified with gold nanoparticles by positioning the sensing element in a gold nanoparticle solution for 2 to 24 hours. The AuNPs-DCC curve is a current-voltage characteristic curve of the sensing element when the sensing element is further modified with N,N′-dicyclohexylcarbodiimide (DCC) after the amino-group chemical modification and the gold nanoparticles modification are completed. The sensing element having completed the amino-group modification, the gold nanoparticles modification, and the DCC modification is now ready for capturing biological materials. As may be seen from FIG. 5, the current-voltage characteristic curve varies with different channel surface modifications.

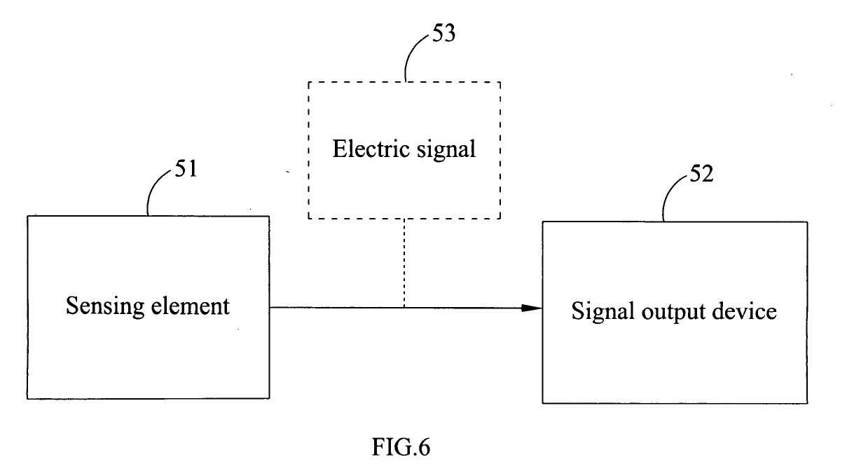

FIG. 6 is a block diagram of a biological detection system according to the present invention. As shown, the biological detection system includes a sensing element 51 having an ultra-thin channel FET, and a signal output device 52. The sensing element 51 may detect an electric signal 53, and the signal output device 52 outputs and records the detected electric signal 53. By observing changes in the electric signal 53, it is able to apply in high-sensitive detection to an analyte.

Preferably, the signal output device 52 is a semiconductor parameter analyzer or other measuring device adapted to detect electric signals. And, the electric signal 53 is preferably a current signal, a voltage signal, or a conductance signal.

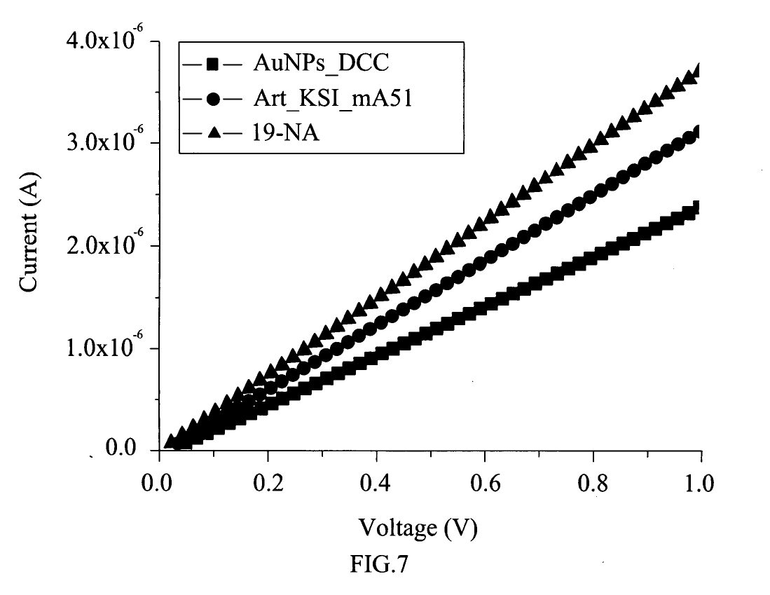

Please refer to FIG. 7, which shows electrical responses of the biological detection system of the present invention in performing biological detection. As shown, the AuNPs_DCC curve is a current-voltage characteristic curve of the biological detection system when the ultra-thin channel surface has been modified with DCC, and the Art_KSI-mA51 curve is a current-voltage curve of the biological detection system when an enzyme KSI-mA51 is immobilized on the ultra-thin channel surface having been modified with DCC. After adding 10⁻⁵ M 19-norandrostenedione, the electrical conductivity of the biological detection system, as indicated by the 19-NA curve, is increased by about 12% due to the influence of molecular antagonism. This indicates the biological detection system with ultra-thin channel FET may be effectively applied to biological detection field.

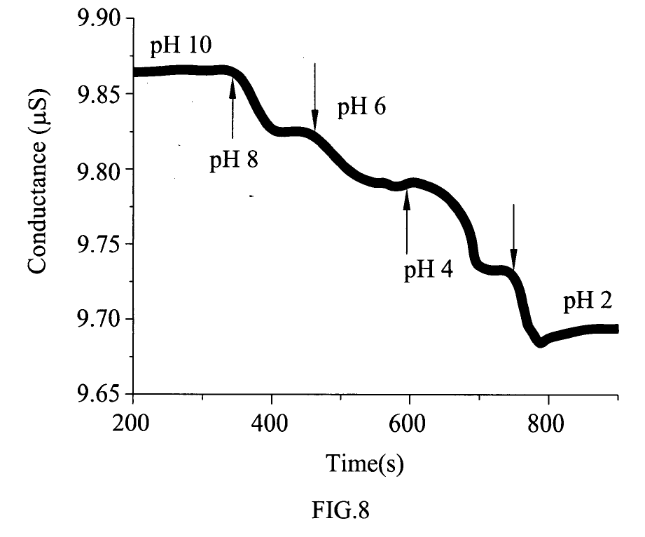

FIG. 8 shows results from tests conducted on buffer solutions with different pH values using the sensing element of the present invention. In FIG. 8, the sensing element after amino-group chemical modification is used to conduct a series of tests on buffer solutions respectively having a pH value of 10, 8, 6, 4, and 2. The test results indicate that, the amino group (—NH₂) will be protonated to amino group (—NH₃⁺) in a buffer solution having relatively low pH value, causing majority carrier holes at the channel to be depleted and thereby resulting in reduction of electrical conducting substance. This also indicates the sensing element of the present invention and the biological detection system employing this sensing element may be effectively used in real-time measurement.

Those skilled in the art would readily appreciate that all parameters listed herein are meant to be exemplary and that actual parameters will depend upon the specific application for which the methods, elements and systems of the present invention are used. It is, therefore, to be understood that the embodiments herein are presented by way of example only and that, within the scope of the appended claims and equivalents thereto, the invention may be practiced otherwise than as specifically described.

What is claimed is:

1. A sensing element comprising:
a field-effect transistor (FET) having an ultra-thin channel, and the ultra-thin channel having a modified surface;
a first passivation layer for enclosing a first portion of the FET;
a second passivation layer for enclosing a second portion of the FET; and
a microchannel being bonded to the first passivation layer and the second passivation layer;
wherein while an analyte to be tested passes through the microchannel and is in contact with the modified surface of the ultra-thin channel, the FET correspondingly generates an electric signal.

2. The sensing element as claimed in claim 1, wherein the ultra-thin channel has a thickness smaller than 50 nm.

3. The sensing element as claimed in claim 1, wherein the FET further includes a substrate;
an insulating layer deposited atop the substrate;
an active layer comprising the ultra-thin channel and deposited atop the insulating layer;
a reference electrode disposed aside the active layer;
a source electrically coupling to the source electrode; and
a drain electrically coupling to the drain electrode.

4. The sensing element as claimed in claim 3, wherein the active layer is made of a material selected from the group consisting of monocrystalline silicon, polycrystalline silicon, and amorphous silicon.

5. The sensing element as claimed in claim 3, wherein the active layer has a thickness smaller than 50 nm.

6. The sensing element as claimed in claim 1, wherein the first passivation layer and the second passivation layer are made of an insulating material.

7. The sensing element as claimed in claim 3, wherein the reference electrode is made of a material selected from the group consisting of gold, platinum, and silver chloride/silver (AgCl/Ag).

8. The sensing element as claimed in claim 1, wherein the microchannel is made of a material selected from the group consisting of silicon, silicon compounds, and organic materials.

9. The sensing element as claimed in claim 8, wherein the organic materials include polydimethylsiloxane (PDMS), polymeric material SU-8, polymethylmethacrylate (PMMA), and cyclic olefin copolymers (COC).

10. The sensing element as claimed in claim 1, wherein the surface of the ultra-thin channel is chemically or physically modified.

11. The sensing element as claimed in claim 10, wherein the surface of the ultra-thin channel is chemically modified with a substance selected from the group consisting of silane coupling agents and metallic complexes.

12. The sensing element as claimed in claim 11, wherein the silane coupling agents include silane coupling agent with amino group, silane coupling agent with carboxyl group, silane coupling agent with aldehyde group, and silane coupling agent with thiol group.

13. The sensing element as claimed in claim 11, wherein the metallic complexes include metallic complex with nickel, metallic complex with iron, metallic complex with gold, metallic complex with silver, and metallic complex with platinum.

14. The sensing element as claimed in claim 10, wherein the surface of the ultra-thin channel is physically modified through non-covalent bonding.

15. The sensing element as claimed in claim 1, wherein the analyte to be tested is a biological material or a chemical substance.

16. The sensing element as claimed in claim 15, wherein the biological material is any one of ribonucleic acid (RNA), deoxyribonucleic acid (DNA), enzymes, proteins, viruses, and lipids.

17. A method of manufacturing a sensing element, comprising the following steps:
(a) providing an FET having an ultra-thin channel, and the ultra-thin channel having a thickness smaller than 50 nm;
(b) defining a reference electrode, a source electrode, and a drain electrode;
(c) depositing a passivation layer;
(d) bonding a microchannel to the passivation layer; and
(e) modifying a surface of the ultra-thin channel to complete the sensing element.

18. The method of manufacturing a sensing element as claimed in claim 17, wherein the reference electrode is made of a material selected from the group consisting of gold, platinum, and silver chloride/silver (AgCl/silver).

19. The method of manufacturing a sensing element as claimed in claim 17, wherein the passivation layer is made of an insulating material.

20. The method of manufacturing a sensing element as claimed in claim 17, wherein the microchannel is made of a material selected from the group consisting of silicon, silicon compounds, and organic materials.

21. The method of manufacturing a sensing element as claimed in claim 20, wherein the organic materials include polydimethylsiloxane (PDMS), polymeric material SU-8, polymethylmethacrylate (PMMA), and cyclic olefin copolymers (COC).

22. The method of manufacturing a sensing element as claimed in claim 17, wherein the surface of the ultra-thin channel is chemically or physically modified.

23. The method of manufacturing a sensing element as claimed in claim 22, wherein the surface of the ultra-thin channel is chemically modified with a substance selected from the group consisting of silane coupling agents and metallic complexes.

24. The method of manufacturing a sensing element as claimed in claim 23, wherein the silane coupling agents include silane coupling agent with amino group, silane coupling agent with carboxyl group, silane coupling agent with aldehyde group, and silane coupling agent with thiol group.

25. The method of manufacturing a sensing element as claimed in claim 23, wherein the metallic complexes include metallic complex with nickel, metallic complex with iron, metallic complex with gold, metallic complex with silver, and metallic complex with platinum.

26. The method of manufacturing a sensing element as claimed in claim 22, wherein the surface of the ultra-thin channel is physically modified through non-covalent bonding.

27. A biological detection system for detecting a biological material, comprising:
a sensing element as that having been described in claim 1 for detecting an electric signal; and
a signal output device for outputting and recording the electric signal;
wherein, a trace detection is conducted on the biological material by observing changes in the electric signal.

28. The biological detection system as claimed in claim 27, wherein the signal output device is a semiconductor parameter analyzer.

29. The biological detection system as claimed in claim 27, wherein the electric signal is a current signal, a voltage signal, or a conductance signal.
